(19) United States
(12) Patent Application Publication
(10) Pub. No.: US 2026/0068679 A1
(43) Pub. Date: Mar. 5, 2026

(54) 3D SHIELD STRUCTURE AGAINST ELECTROMAGNETIC INTERFERENCE FOR A SEMICONDUCTOR DEVICE

(71) Applicant: STMicroelectronics International N.V., Geneva (CH)

(72) Inventors: Deborah COGONI, Notre Dame de l'Osier (FR); Vipin VELAYUDHAN, Grenoble (FR)

(73) Assignee: STMicroelectronics International N.V., Geneva (CH)

(21) Appl. No.: 19/304,005

(22) Filed: Aug. 19, 2025

(30) Foreign Application Priority Data
Aug. 28, 2024 (FR) FR2409165

(51) Int. Cl. H01L 23/552; H01L 21/48; H01L 23/498

(52) U.S. Cl. CPC H01L 23/552

(57) ABSTRACT

Semiconductor device includes an integrated circuit package having a connection array for a connection to a printed circuit. The integrated circuit package includes a shield structure against electromagnetic interference from elementary connectors, such as balls. The shield structure is formed by deposition by 3D printing of a metal shield wall between the elementary connectors.

### PRIORITY CLAIM

This application claims the priority benefit of French Application for Patent No. FR2409165, filed on Aug. 28, 2024, the content of which is hereby incorporated by reference in its entirety to the maximum extent allowable by law.

### TECHNICAL FIELD

The present invention relates to the shielding of a printed circuit (PCB) against electromagnetic interference (EMI) generated by various elementary components of the printed circuit and, in particular, to shielding electromagnetic interference within a connection array of the solder ball (BGA), connection land (LGA) or connection pin (PGA) type.

### BACKGROUND

An electric current flowing in the components of a printed circuit generates an electromagnetic field. An electromagnetic signal then propagates with an electric field component and a magnetic field component, which can cause electromagnetic interference between the components themselves. The electromagnetic interference is the generation of undesirable electrical signals in the circuits of electronic systems due to the unintentional coupling of the energy of an incident electromagnetic field.

In highly compact electronic systems, the size of the average circuit element or component is decreasing, which promotes the radiation of higher frequency signals. The increasingly high operating frequency of these electrical systems leads to a high level of high-frequency electromagnetic interference (EMI). The predominance of high-frequency systems and mobile electronic circuits is creating a very complex environment for the operation of sensitive electrical/electronic systems. Consequently, it is often advantageous to shield an electrical/electronic component against EMI emitted by other components.

Sensitive or radiating electrical components can be covered with a metal cover and/or enclosure providing a shield that is connected to a ground plane during the process of fixing the cover in place. Existing shields have limited capability for reuse and are dedicated to individual components. These shields are often metal plates, perforated plates, cages or meshes, which cover an entire circuit or certain specific components.

Metal shields are often expensive, heavy and difficult to miniaturize in order to shield the components, in particular, against internal EMI.

There is therefore a need for shields against internal EMI for certain components.

It has been observed that electrical currents flowing in elementary connector arrays are sources of EMI between the elementary connectors.

A connection array is a very small size assembly of connectors (less than a millimeter) which can electrically connect an integrated circuit package to a printed circuit.

The connection array can be of the ball grid array (BGA) type, where the elementary connectors are balls of solder, land grid array (LGA) type, where the elementary connectors are connection lands (pads), or pin grid array (PGA) type, where the elementary connectors are connection pins, or else column grid array (CGA) type, where the elementary connectors are columns of solder.

It is therefore desirable to reduce the EMI between elementary connectors.

It is important to limit the EMI between these elementary connectors with a shield device which can adapt to the complex shapes of elementary connectors disposed on the connection array.

### SUMMARY

In an embodiment, a semiconductor device comprises an integrated circuit package having a connection array for connection to a printed circuit. The integrated circuit package comprises a shield structure against electromagnetic interference from elementary connectors of connection elements, formed by a metal deposition forming a shield wall between the elementary connectors.

Thus, the EMI emitted by the elementary connectors is reduced by the metal wall between them.

When the EMI comes into contact with the shield wall, the metal wall reflects the majority of electromagnetic waves, while part of the EMI is absorbed and converted into heat. The remaining energy is confined within the metal wall due to the skin effect, thus preventing the EMI from reaching sensitive electronic components on the other side of the metal wall.

The metal walls can reflect and absorb EMI as well as generating the skin effect for EMI, which makes the metal walls particularly effective for blocking EMI, thus shielding the electronic components from EMI.

In an embodiment, the metal wall is electrically connected to a ground track of the integrated circuit.

The metal wall can absorb the electrical signals induced by the electromagnetic interference emitted by the elementary connectors and conduct these electrical signals to the ground plane of the circuit package.

In particular, at least one part of the metal wall is deposited directly on the ground track. Further, the ground track may have been uncovered between the elementary connectors, before deposition of the metal wall. This disposition makes it possible to produce, in a single operation (metal deposition), the EMI shield and its electrical connection to the ground plane.

Advantageously, the shield structure comprises an insulating layer covering the metal wall.

The insulating layer can thus avoid a short-circuit between the elementary connectors during connection of the connection array to the printed circuit. More specifically, during connection of the array to the printed circuit, these elementary connectors can be soldered to the printed circuit or be compressed, creating a risk of contact with the shield wall. The insulating layer therefore prevents electrical contact, and thus uncontrolled electrical pathways.

The connection array is preferably at least one of a pin grid array (PGA), a ball grid array (BGA), a land grid array (LGA) or a column grid array (CGA).

Advantageously, the shield structure has a height substantially equal to a height of the elementary connectors after connection of the array to the printed circuit. The height is defined along the normal to the plane of the connection array.

During soldering or compression of the elementary connectors, the height of the elementary connectors is often reduced by the effect of applied heat or forces. The height of the shield structure is chosen substantially equal to the height of the elementary connectors after connection of the array to the printed circuit in order to form an EMI barrier over the entire height between the semiconductor device and the printed circuit.

In an embodiment, the connection array is disposed on a lower face of a support printed circuit of the integrated circuit package, the shield structure comprising at least one first shield portion formed by metal deposition on a lateral edge of the support printed circuit.

A support printed circuit generally comprises of a plurality of internal layers, with alternating dielectric and conductive layers. The electrical current flowing in these conductive layers generates non-negligible EMI. By forming at least one shield portion on a lateral edge of the printed circuit, preferably at the height of the highly emitting zones, the emission of EMI from the support printed circuit is greatly reduced.

Advantageously, the at least one first shield portion has the form of a comb extending over a portion of the lateral edge of the printed circuit. A comb is formed, for example, of a multitude of substantially parallel fingers or strands, extending over the lateral edge.

The first portion in the form of a comb advantageously enables a quick formation, for example by 3D printing, while reducing the material required to form a shield structure against the EMI.

The first shield portion can extend over the entire thickness of the support printed circuit or over only a part of the support printed circuit in the case where the conductive layers with high EMI emission are low layers in the support printed circuit, for example.

In an exemplary embodiment, the at least one first shield portion extends beyond the thickness of the printed circuit, up to a height of the electrical components disposed on the support printed circuit. This embodiment also reduces the EMI of these electrical components.

In an embodiment, the shield structure comprises a second shield portion, produced by metal deposition, forming a peripheral frame of the lower face of the support printed circuit.

The current flowing on the edge of the support printed circuit is thus limited. The shield portion in the form of a comb can extend, in particular, on the lateral edge of the printed circuit from the portion forming a peripheral frame of the carrier PCB.

In an embodiment, the metal wall, the insulating layer, and the first and the second portions where appropriate, are deposited on the carrier substrate by 3D printing.

3D printing of the shield structure is particularly advantageous because it enables the metal wall, the insulating layer and the shield portion to be deposited in a more effective and more ergonomic manner. 3D printing also enables miniaturizing of the shield structure formed between the elementary connectors and adaptation of the shapes of the shield structure to the complex geometries of the connection array.

Preferably, the shield structure forms a grid of mutually perpendicular rectilinear metal walls, disposed between the elementary connectors organized in a grid pattern within the array.

The grid with perpendicular lines often corresponds to the position of the elementary connectors. This arrangement allows for better insulation of EMI emissions at the elementary connector level.

A further embodiment concerns a method for manufacturing a semiconductor device comprising the following steps: obtaining an integrated circuit package having a connection array for connection to a printed circuit; and forming a shield structure against electromagnetic interference between the elementary connectors by metal deposition forming a shield wall between the elementary connectors.

In an embodiment, the formation of the shield structure further comprises one or more operations from: a step of depositing an insulating layer on the shield wall; a step of metal deposition on a lateral edge of a metal support printed circuit on the lower face of which the connection array is disposed, so as to form a lateral shield portion, optionally having the form of a comb; and a step of metal deposition forming a peripheral frame of the lower face of the support printed circuit.

According to an embodiment, the one or more metal depositions and the deposition of the insulating layer where appropriate are carried out by 3D printing.

### BRIEF DESCRIPTION OF THE DRAWINGS

FIG. 1 illustrates a semiconductor device comprising a circuit package connected to a connection printed circuit board (PCB).

FIGS. 2A, 2B and 2C illustrate a semiconductor device comprising a circuit package with a shield structure.

FIGS. 3A, 3B and 3C illustrate a deposition of a shield structure between elementary connectors.

FIG. 4 illustrates a shield portion deposited on a lateral side of a printed circuit.

FIG. 5 is a flow diagram of a method for manufacturing a semiconductor device comprising a shield structure against electromagnetic interference between the elementary connectors.

### DETAILED DESCRIPTION

For clarity, the same elements bear the same references in the different figures. Moreover, the various figures are not plotted to scale, as is usual in the representation of integrated circuits.

In the description, when reference is made to absolute position qualifiers, such as the terms “front”, “rear”, “top”, “bottom, “left”, “right”, etc., or relative position qualifiers, such as the terms “above”, “below”, “upper”, “lower”, etc., or to orientation qualifiers, such as the terms “horizontal”, “vertical”, etc., reference is made unless otherwise specified to the orientation of the figures or to an electronic circuit in a normal position of use. Unless otherwise specified, the expressions “around”, “approximately”, “substantially”, and “of order” mean to within 10%, preferably to within 5%. In the remainder of the description, the term “conductive” means electrically conductive and the term “insulating” means electrically insulating.

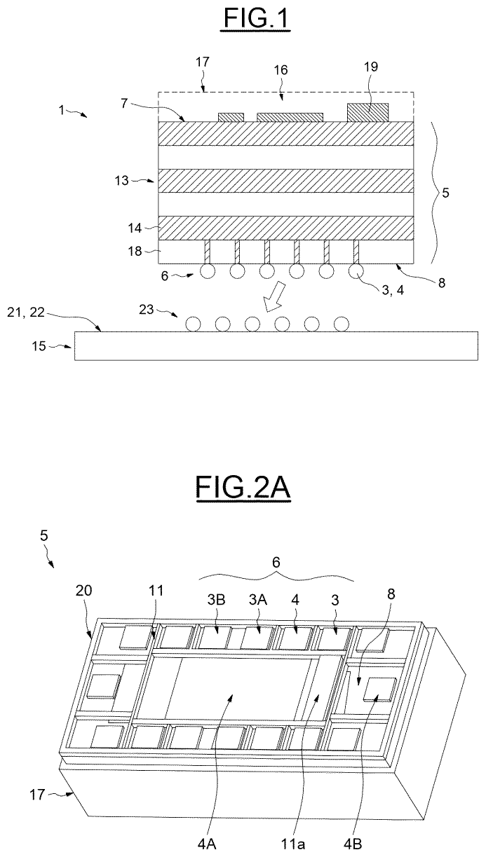

FIG. 1 illustrates a semiconductor device comprising an integrated circuit package 1. The assembly is designed to be connected to a connection printed circuit board or PCB 15 via a connection array 6 formed of elementary connectors 3, 4 as described below.

In a known manner, the integrated circuit package 1 comprises an integrated circuit 16 covered by a cover 17 that is typically made of resin.

The integrated circuit 16 is formed of a “carrier” or “support” printed circuit board (PCB) 5 on the (upper) mounting surface 7 of which one or more electronic components 19 are mounted forming an integrated circuit 16 assembly. By way of example, an electronic component can comprise a semiconductor chip, which is a semiconductor integrated circuit device such as a microprocessor, a memory, a logic device, an analog device or any other electronic function implemented in an integrated circuit with a single chip, as known in the prior art.

The carrier PCB 5 is generally composed of a substrate 18 and a plurality of successive layers (conductive then dielectric track). The conductive layers being connected together by internal connections (not shown), for example vias or metallized holes.

The electrical components are electrically connected to the tracks of the carrier PCB 5. The substrate of the carrier PCB 5 can be a substrate made of ceramic, epoxy resin, glass fabric or paper. Opposite the mounting face 7, the carrier PCB 5 comprises a connection face 8 comprising a connection array 6. The connection array 6 is configured to electrically connect the integrated circuit package 1 to the connection PCB 15 (which comprises a complementary connection array 21).

In the design process, the cover 17 is deposited on the mounting face 7 of the carrier PCB 5 so as to cover the electronic components 19 mounted on the surface. In this configuration, the edges 13 (or lateral faces) of the carrier PCB 5 are not covered by the resin of the cover 17.

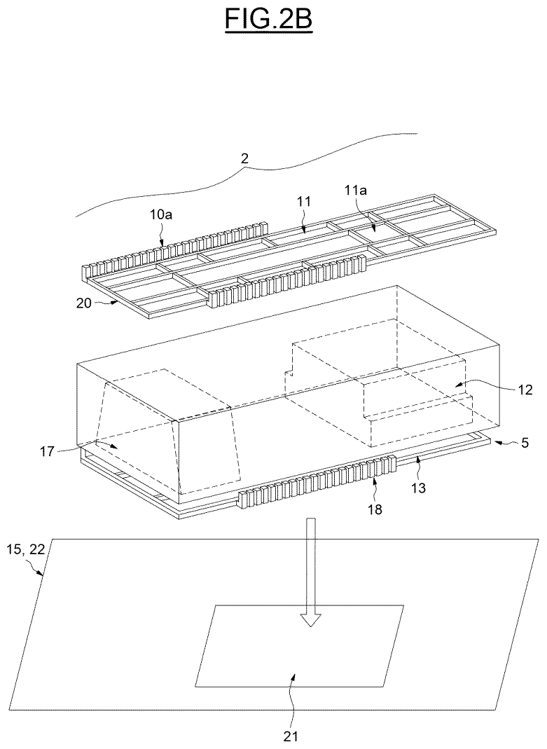

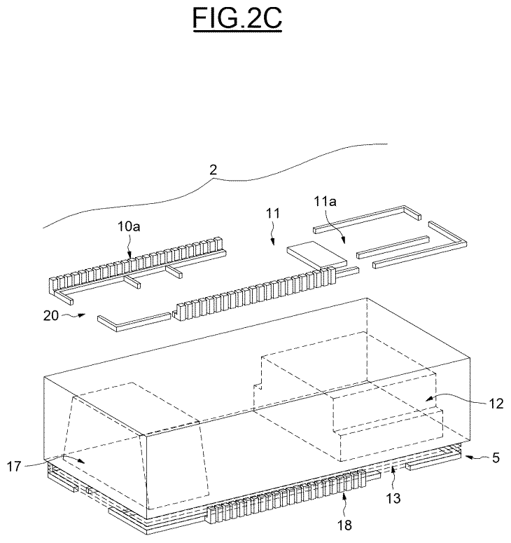

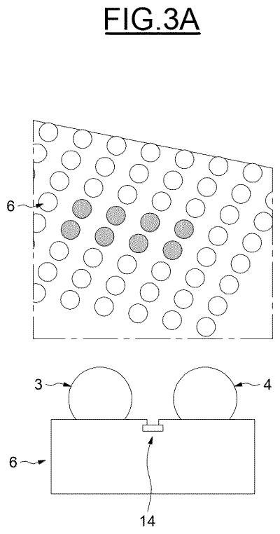

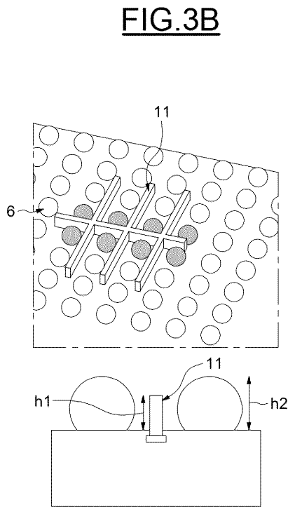

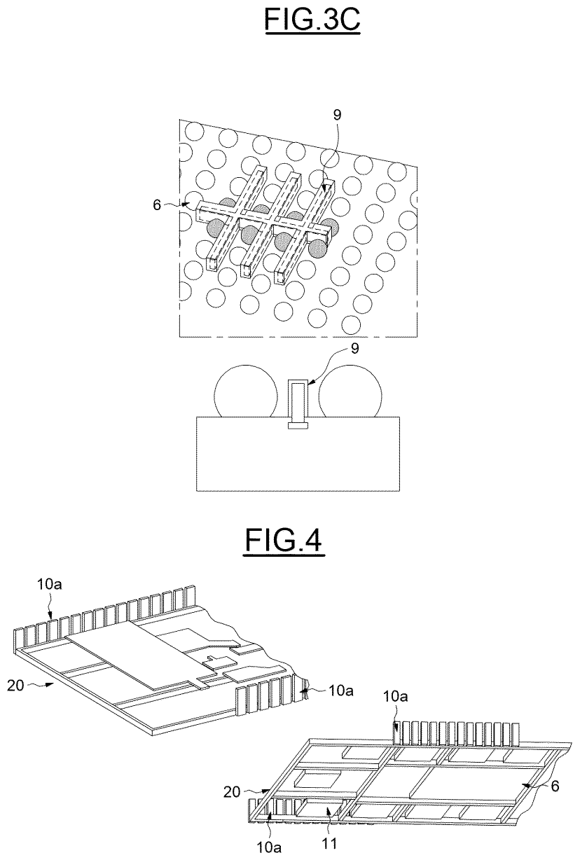

The connection array 6 comprises a plurality of elementary connectors 3, 4. In a non-limiting example, the connection array 6 is a pin grid array (PGA), a ball grid array (BGA), a land grid array (LGA) or a column grid array (CGA). The elementary connectors 3, 4 can be organized in a regular grid (with regular rows and columns; see for example FIG. 3A-3B) or in a less regular manner (FIGS. 2A-2B).

In known manner, the connection PCB 15 comprises an alternation of conductive layers and insulating or dielectric layers, the conductive layers being connected to one another by internal connections, for example vias or metallized holes. A so-called connection face 22 includes complementary elementary connectors 23 (see, FIG. 1) to those of the integrated circuit package 1: for example, lands, through-holes or else sockets.

Thus, the integrated circuit package 1 can be electrically connected to the connection PCB 15 via balls, lands, columns, pins or other known elementary connectors, by aligning these elementary connectors with their respective connection faces.

The connection between the integrated circuit package 1 and the connection PCB 15 can be provided by soldering, bonding, insertion, compression or any other known connection means. In a preferred example, the elementary connectors 3, 4, such as the lands or balls, are soldered in order to provide the electrical connection.

The carrier PCB 5 includes an insulating layer 18 forming the outer surface of the connection face 8, and under the insulating layer 18 (at the bottom in the figure), a ground track 14 connected in known manner to a ground plane in order to remove any undesirable current (e.g., leakage current). In a preferred example, the ground track 14 forms the layer immediately after the insulating layer 18 forming the outer surface of the carrier PCB 5.

In an embodiment, the ground track 14 is located between the elementary connectors 3, 4, for example between each row of elementary connectors 3, 4, as illustrated in FIG. 3A-3B. In another embodiment, a terminal of the ground track 14 can be disposed outside of the connection array 6 in order to be connected by an electrical wire (technology referred to as “wire bonding”) to the EMI shield structure according to the present disclosure.

FIG. 2A illustrates a semiconductor device comprising a circuit enclosure with an EMI shield structure 2. FIG. 2B illustrates the connection between the carrier PCB 5 and the connection PCB 15. In order to limit the electromagnetic interference emitted by the elementary connectors 3, 4, the shield structure 2 is formed by a metal deposition forming a shield wall or ridge 11, disposed vertically (relative to the connection array 6 and therefore to the plane of the insulating layer 18 or a connection face 8), between the elementary connectors 3, 4.

The shield wall 11 can be deposited, for example, without wishing to be limiting, by chemical vapor deposition (CVD), plasma-enhanced chemical vapor deposition (PECVD), cathode sputtering, evaporation, screen printing, spraying, plating or 3D printing. In an example, 3D printing is preferred. 3D printing can involve at least one from selective laser sintering (SLS), stereolithography (SLA), fused deposition modelling (FDM), multi jet fusion (MJF), direct metal laser sintering (DMLS), PolyJet or Carbon DLS (Digital Light Synthesis).

FIGS. 3A-3C illustrate an embodiment of manufacturing of the EMI shield structure 2. In this case, it involves producing the EMI shield structure for a ball grid array regularly distributed in the form of a grid.

In a first step illustrated in FIG. 3A, the insulating layer 18 of the carrier PCB is etched. The insulating layer 18 can be etched substantially in the middle between two elementary connectors 3, 4 as illustrated, so as to expose the ground track 14. The etching can be at a point, in order to form a localized connection terminal, or be extended in the form of a groove, in particular with one or more longitudinal sections between the elementary connectors 3, 4, in the form of one or more shield walls 11 to be created.

The insulating layer 18 can also be etched at an end of the carrier PCB 5 outside of the connection array 6.

In a second step illustrated in FIG. 3B, a metal deposition of the shield wall 11 between the elementary connectors 3, 4 is carried out, typically by 3D printing. The metal deposition typically has a longitudinal deposition forming ridges. In the example of FIG. 3B, the shield structure 2 forms a grid of mutually perpendicular rectilinear metal walls 11, disposed between the elementary connectors 3, 4 and organized in a grid pattern within the connection array 6.

As shown in FIG. 3B, the shield structure 2 has a height h1 (along the axis perpendicular to the plane of the connection array 6) substantially equal to a height h3 (not illustrated) of the elementary connectors 3, 4 after connection of the connection array 6 to the connection PCB 15. The height h2 of the elementary connectors 3, 4 illustrated in FIG. 3B, corresponds to the height of the connectors before the connection of the array 6 to the connection PCB 15. More specifically, the height h2 of the connection balls 3, 4 is intended to be reduced under the effect of, for example, soldering operations.

Thus, the shield structure 2 does not exceed (except for design uncertainties) the height h3 of the elementary connectors 3, 4 after fixation to the connection PCB 15 and therefore does not interfere with the connection of the connection array 6 to the connection PCB 15.

In a non-limiting example, in which connection balls are used as the elementary connectors 3, 4, the height h2 is between 200 and 500 micrometers before connection of the array 6 to the connection PCB 15. The height h3 of the elementary connectors 3, 4 after the connection of the connection array 6 is between 50 and 150 μm. Further, the metal deposition is preferably produced over a height between 50 and 150 μm

In a non-limiting example, the distance between the elementary connectors 3, 4 and the shield wall 11 is between 100 and 500 μm, more particularly between 150 and 250 μm, for example 200 μm. In a non-limiting example, the width of the shield wall 11 is between 10 and 50 μm, typically offering several tens of micrometers of space with the elementary connectors 3, 4. In general, 3D printing techniques enable a deposition of metal drops with a width of 10 μm.

The dimensions above, for example the height of 150 μm for a width of 10 to 50 μm, shows that the shield wall 11 extends vertically relative to the plane of the connection face 8.

At least a part of the metal deposition is produced on the exposed ground track 14, on the localized connection terminal or on the longitudinal sections, depending on the case, ensuring the electrical connection of the wall 11 to the ground plane. The lower illustration of FIG. 3B shows that the anchoring of the wall 11, and therefore its mechanical strength, are improved by the etching of the insulating layer 18. Further, in an embodiment, the etching has been performed over all of the zones where the metal deposition must be produced.

Thus, the shield wall 11 can be directly deposited by metal deposition in the groove between the elementary connectors 3, 4 which makes it possible to both produce the electrical connection to the ground track 14 and to improve the retention of the shield wall 11 in a position perpendicular to the mounting face 7 of the carrier PCB 5. The shield wall 11 is thus better fixed to the connection array 6.

The shield wall 11 can absorb an EMI electromagnetic signal emitted by the elementary connectors 3, 4. The signal thus absorbed by the shield wall 11 is then conducted to the ground track 14.

In an optional third step, illustrated in FIG. 3C, an electrically insulating layer 9 is deposited on the shield wall 11 by the same deposition means as the shield wall 11 previously described. The insulating layer 9 can be one from an insulating layer of silicon oxide, an epoxy resin, an FR4 composite, a silicone polymer resin or insulating polymers.

One or more layers of 10 μm thickness can be deposited by 3D printing.

The insulating layer 9 can thus avoid a short-circuit between the elementary connectors 3, 4 during connection of the connection array 6 to the connection PCB 15.

As illustrated in FIG. 2A, the shield wall 11 can be deposited between each elementary connector 3, 4, such as the pads in this non-limiting example. The shield wall 11 can be deposited around a central elementary connector 4A of the connection array 6, in order to isolate it from elementary connectors placed around it.

At certain sites on the connection array 6, the metal deposition can be produced over an extended width relative to the height, typically to form a plate 11a between elementary connectors 4A and 4B, in, for example, a strongly emitting zone of the carrier PCB 5.

In an embodiment such as that illustrated, the shield structure 2 can also comprise a portion deposited on the peripheral frame 20 of the carrier PCB 5, preferably connected to the one or more shield walls 11 between the elementary connectors 3, 4. The electromagnetic emissions (EM) at the edge of the carrier PCB 5 are reduced.

Through the localized metal deposition, the shield structure 2 has a modular structure that can take the form necessary for limiting EMI emissions from some or all of the elementary connectors 3, 3A, 3B, 4, 4A, 4B.

In a particular example, the metal deposition of the shield structure 2 is performed between all the elementary connectors 3, 4 of the connection array 6. In FIG. 2A, this is not the case, for example between the elementary connectors 3A and 3B. The metal deposition forming a shield wall 11 can be carried out in only the strongest EMI emission regions, determined by numerical simulation of the integrated circuit package 1, analyzed by suitable software or a detector that is specially designed to identify EMI present.

The additive manufacturing of the shield structure 2 by 3D printing as a preferred example, allows a high degree of freedom in the form and/or the particular dimensions of the shield structure 2. Thus, only the most highly emitting of the elementary connectors 3, 4 can be covered by the shield structure 2 which makes it possible to accelerate the deposition of the shield structure and to limit the expenditure of metal material used for the deposition of the shield structure 2.

In an embodiment, in which soldering is used as a means for connecting the array 6 to the connection PCB 15, a solder flux is applied on the elementary connectors 3, 4 and/or on the connection array 6. The solder flux ensures a better soldering and desoldering process by removing oxide films which form at the surface of the elementary connectors 3, 4 which are to be soldered to the connection PCB 15.

Thus, during the deposition of the shield structure 2, openings in the shield wall 11 can be provided which enable flow of the solder flux.

For example, the height h1 of the shield structure 2 can be reduced at predetermined locations between the elementary connectors 3, 4 in order to allow the solder flux to pass.

Alternatively, the shield structure 2 can be an open geometric shape (as in FIG. 3C). FIG. 2C also illustrates such a variant in which shield walls 11 are only formed between certain elementary connectors.

During soldering, a high temperature can be applied in order to solder the elementary connectors 3, 4 to the connection PCB 15. After soldering, the solder flux residues in the solder process can be removed by an air pressure, for example, passed between the openings in the shield structure 2.

With reference to FIGS. 2A-2C and FIG. 4, the shield structure comprises at least one first shield portion 10a formed by metal deposition on a lateral edge 13 of the carrier PCB 5. For reasons of clarity, the lateral edges 13 are visible only in FIG. 2C but they are also present in the embodiments of FIGS. 2A-2B. This shield portion 10a, referred to as the lateral shield portion, can be formed during the same metal deposition operation as that of the metal wall 11 described previously.

In particular, as illustrated, the lateral shield portion 10a can extended on the lateral edge 13 from the portion 20 forming the peripheral frame of the carrier PCB. Similarly, a plurality of portions 10a are formed on several sides of the carrier PCB 5.

A lateral shield portion 10a can comprise a plurality of strands or fingers that are connected together and having the form of a comb extending over all or part of the lateral edge 13 of the carrier PCB 5. The use of a portion in the form of a comb makes it possible to reduce the deposition of metal material during the deposition of the shield portion 10a and to keep the integrated circuit package 1 sufficiently lightweight. The deposition time is also reduced. Alternatively, the lateral shield portion 10a is in the form of a continuous plate.

The zones where these shield portions are deposited in the form of a comb correspond preferably to the zones of high EM emission, which can be determined by numerical simulation of the integrated circuit package 1.

The lateral shield portion 10a can extend over the entire height of the carrier PCB 5, or over only a part of this (for example half-height or 75% of the height), depending for example on whether the strongly emitting zones/layers of the carrier PCB 5 are placed more or less high in the carrier PCB 5.

In an embodiment, the lateral shield portion 10a extends beyond the thickness of the carrier PCB 5, on the side of the resin cover 17, up to a height of the electrical components 19 making it possible to also reduce the EMI generated by these electrical components.

The lateral shield portion 10a may take various forms such as a comb, a plate, a plate with openings or a wall inclined towards the connection array 6 forming an angle that is not perpendicular to the plane of the array.

The table below presents the comparative tests carried out on the integrated circuit package 1 with the shield structure 2 deposited, in comparison with an integrated circuit package without shield structure.

“Zpos”, “Ypos”, “Yneg”, “Xpos” and “Xneg” are the electromagnetic field measurements in the integrated circuit package 1 along the various axes X, Y and Z. Three embodiments were studied for a same integrated circuit package 1.

In the first embodiment, interconnections by wire (known as “wire bonding”) between the electrical components in the package 1 were replaced by the metal deposition (3D printing) of a metal connection strip, in order to reduce the EMI emissions of the interconnections.

In the second embodiment, only the shield walls 11 between the pads 3, 4 of the connection array 6 as well as the peripheral frame format portion 20 were formed by metal deposition on the package 1. The internal interconnections remain wire interconnections.

In the third embodiment, the wire interconnections 20 were replaced by metal connection strips, the shield walls 11 between the pads 3, 4 of the connection array 6 as well as the peripheral frame format portion 20 were formed by metal deposition. In addition, portions in the form of a comb were formed on certain edges identified as strongly emitting.

The table below shows that the third EMI shield embodiment provides a significant reduction in the electric “E” and magnetic “H” fields around the package 1 along all the axes examined.

| | Zpos | | Ypos | | Yneg | | Xpos | | Xneg | |
|---|---|---|---|---|---|---|---|---|---|---|
| Embodiment | E | H | E | H | E | H | E | H | E | H |
| 1^{st} | −4% | −20% | −1% | −3% | −2% | −36% | −2% | −34% | −1% | −3% |
| 2^{nd} | −5% | −6% | −42% | −20% | −28% | +16% | −26% | +1% | −46% | −20% |
| 3^{rd} | −13% | −30% | −46% | −26% | −51% | −23% | −27% | −36% | −52% | −26% |

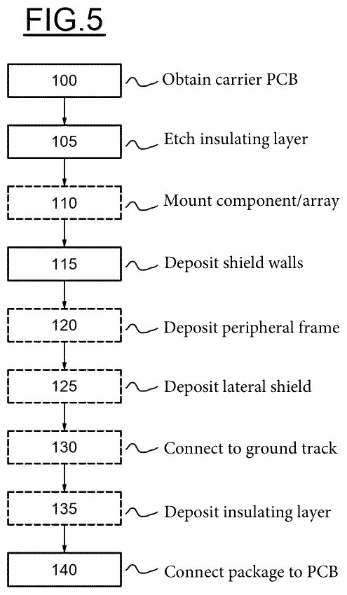

A flow diagram of a method for manufacturing the semiconductor device is illustrated in FIG. 5.

The carrier PCB 5 is obtained in the first step 100. It may or may not already comprise the connection array 6, the electrical components 19 and the resin cover 17.

In the second step 105, the insulating layer 18 of the carrier PCB 5 is etched in order to expose the ground track 14 between the elementary connectors 3, 4, in the form of a localized connection terminal or longitudinal sections.

In optional step 110, the electronic component 19 and/or the connection array 6 (for example the balls) are mounted on the mounting face 7 of the carrier PCB 5, if necessary. The resin cover 17 can also be deposited on the carrier PCB 5 according to conventional techniques.

In the following step 115, a metal deposition is produced between the elementary connectors 3, 4. The metal deposition forms the shield wall 11 against electromagnetic interference between the elementary connectors 3, 4. If the ground track 14 has been exposed on a zone where the metal deposition takes place, the electrical connection of the wall 11 to the ground track 14 is produced in this step. In a preferred example, the metal deposition is produced by 3D printing.

In optional step 120, the portion forming peripheral frame 20 of the carrier PCB 5 is deposited on the mounting face 7. The metal deposition is produced by 3D printing in a preferred example, during the same 3D printing operation as step 115.

In optional step 125, the lateral shield portion 10a in the form of a comb is deposited on the lateral parts of the package 1. In a preferred example, the metal deposition is produced by 3D printing, during the same 3D printing operation as step 115 and/or 120.

In optional step 130, the electrical connection to the ground track 14 is produced by electrical wire between the wall 11 and the exposed localized connection terminal. This step is carried out in the case where the electrical connection has not been produced during the metal deposition 115 of the shield wall 11.

In optional step 135, a deposition of the insulating layer 9 on the shield walls 11 is carried out. In a preferred example, the metal deposition is produced by 3D printing.

In the following step 140, the connection of the integrated circuit package 1 to the connection PCB 15 is carried out via their respective connection arrays 6. This connection can be produced by soldering.

### REFERENCE LABELS

1—integrated circuit package; 2—shield structure; 3, 4, 3A, 4A, 4B—elementary connectors; 5—carrier PCB; 6—connection array; 7—carrier PCB mounting face; 8—carrier PCB connection face; 9—insulating layer; 10a—lateral shield portion; 11—shield wall; 11a—plate; 13—lateral edge; 14—ground track; 15—connection PCB; 16—integrated circuit; 17—integrated circuit package cover; 18—carrier PCB insulating layer; 19—electronic component; 20—carrier PCB peripheral frame; 21—complementary connection array; 22—connection PCB connection face; and 23—complementary elementary connectors.

1. A semiconductor device, comprising:
an integrated circuit package having a connection array of elementary connectors on a carrier printed circuit for connection to a connection printed circuit;
wherein the integrated circuit package comprises a shield structure against electromagnetic interference from the elementary connectors, said shield structure formed by a metal deposit on the carrier printed circuit which forms a shield wall between elementary connectors.

2. The semiconductor device according to claim 1, wherein the shield wall is electrically connected to a ground track of the carrier printed circuit.

3. The semiconductor device according to claim 2, wherein at least one part of the shield wall is positioned directly on the ground track.

4. The semiconductor device according to claim 1, further comprising an insulating layer covering the shield wall of the shield structure.

5. The semiconductor device according to claim 1, wherein the connection array is at least one of: a pin grid array, a ball grid array, a land grid array or a column grid array.

6. The semiconductor device according to claim 1, wherein the shield structure has a height along an axis perpendicular to a plane of the connection array, wherein said height is substantially equal to a height of the elementary connectors after connection of the connection array to the connection printed circuit.

7. The semiconductor device according to claim 1, wherein the connection array is formed on a lower face of the carrier printed circuit of the integrated circuit package, and wherein the shield structure comprises at least one first shield portion formed by a metal deposit on a lateral edge of the carrier printed circuit.

8. The semiconductor device according to claim 7, wherein the at least one first shield portion has a form of a comb extending over a portion of the lateral edge of the carrier printed circuit.

9. The semiconductor device according to claim 7, wherein the shield structure comprises a second shield portion, formed by a metal deposit, forming a peripheral frame of the lower face of the carrier printed circuit.

10. The semiconductor device according to claim 9, wherein the shield wall, the first and the second shield portions, and the insulating layer, are 3D printed structures on the carrier printed circuit.

11. The semiconductor device according to claim 1, wherein the shield structure forms a grid of mutually perpendicular rectilinear metal walls disposed between the elementary connectors organized in a grid pattern within the connection array.

12. A method for manufacturing a semiconductor device, comprising the steps of:
obtaining an integrated circuit package having a connection array of elementary connectors on a carrier printed circuit for connection to a connection printed circuit; and
forming a shield structure against electromagnetic interference on the carrier printed circuit between the elementary connectors by metal deposition forming a shield wall between the elementary connectors.

13. The method for manufacturing according to claim 12, wherein forming the shield structure comprises 3D printing the metal deposition forming the shield wall.

14. The method for manufacturing according to claim 12, further comprising depositing an insulating layer on the shield wall.

15. The method for manufacturing according to claim 12, further comprising metal depositing on a lateral edge of the carrier printed circuit to form a first lateral shield portion.

16. The method for manufacturing according to claim 15, wherein the first lateral shield portion has a form of a comb.

17. The method for manufacturing according to claim 12, further comprising metal depositing a second shield portion forming a peripheral frame of a lower face of the carrier printed circuit.
